(19) United States
(12) Patent Application Publication
(10) Pub. No.: US 2002/0118031 A1
(43) Pub. Date: Aug. 29, 2002

(54) Connector test card

(75) Inventors: Edward C. Sweeney, Princeton, MA (US); Joel M. Appelbaum, Bedford, MA (US); Paul C. Naumann, Medfield, MA (US)

Correspondence Address: NUTTER MCCLENNEN & FISH LLP, ONE INTERNATIONAL PLACE, BOSTON, MA, 02110, US

(73) Assignee: Equipe Communications Corporation

(21) Appl. No.: 09/794,602

(22) Filed: Feb. 27, 2001

(51) Int. Cl. G01R 31/02

(52) U.S. Cl. 324/755

(57) ABSTRACT

Connector test cards provide for improved printed circuit board (“board”) testability by terminating each etch routed to an unmated connector on the board. With the connector test card mated with the connector on the board under test, the integrity of solder joints between the connector and the board may be tested for opens and shorts on a standard in-circuit or fixtureless tester. In addition, during functional testing, a connector test card may be mated with a connector on the board to prevent the voltage levels on undriven component inputs on the board from floating.

### BACKGROUND

In typical computer systems, including telecommunications network devices (e.g., routers, switches, hybrid router/switches), connectors are often used to electrically connect complex integrated circuit components (“components”) to printed circuit boards (“boards”). A connector receptacle mounted to a board connects with a component by receiving the component's pins. In addition, connectors are also often used to electrically connect two boards together. For example, two boards may be connected together as a mother board and a daughter board pair, and as another example, one board may be a backplane or midplane and may be connected to several other boards. When two boards are connected together, one board includes a connector plug with pins and the other board includes a connector receptacle to receive the connector plug's pins. Today's computer systems include boards that are generally densely packed with components and, thus, connectors are also required to provide a large number of connections in a very small area. For example, NeXLev™ High-Density Parallel Board Connectors (“NeXLev”) manufactured by Teradyne, Inc.—Connections Systems Division provide 145 signals per inch. One part number, for example, 470-2025-100 2.5 mm NeXLev plug includes 200 signal pins and 180 ground pins and part number 470-2105-100 10.5 mm NeXLev receptacle receives each of the plug's signal and ground pins. Other part numbers with the same number of pins/sockets and part numbers of different sizes and with more and less pins/sockets are also available. Other high density connectors are also available from other manufacturers, for instance, Berg FCI Corporation manufactures the Megarray™ connector.

To achieve the necessary densities, the connector packages—both the plug and receptacle—are often ball grid arrays (“BGA”) to allow for a surface mount (SMT) attachment process. The difficulty with BGA connectors is that once mounted to a board it is very difficult to test the integrity of the solder joints between each ball pad on the connector and each pad on the board. A visual inspection is not possible since the ball pads are between the connector package and the board and, thus, the BGA solder joints are not visible. X-ray testing is often used to test the integrity of the solder joints and is good at detecting a short between ball pads—that is a solder bridge running between one ball/board pad solder joint and another ball/board pad solder joint. However, X-ray testing is insufficient for detecting opens between ball pads and board pads—that is an inadequate solder joint between a ball pad and a board pad.

In-circuit or fixtureless testing, using, for example, a Takaya APT 8400 built by Itochu Corporation, is also often used to test for opens and shorts across a board (“board under test”). Unfortunately, this type of tester is also insufficient for testing BGA connectors for opens. An in-circuit tester tests one board at a time and each etch under test must be terminated. Each etch routed to a connector plug or receptacle is generally terminated on the other board or component to which the connector plug or receptacle is to be connected. Thus, when a board is tested with the connector plug or receptacle alone, each etch routed to the connector is not terminated and the in-circuit tester detects all such etch as opens across the connector, whether they are valid opens or not. In fact, because each etch routed to the connectors are not terminated, an in-circuit tester may not even detect an entirely missing connector. In addition, the tester connects with surface pads on one side of the board and cannot connect with each pin in the connector. Moreover, even if the tester could connect with each pin, the connector may be on the wrong side of the board for testing.

If a BGA connector includes an undetected open, a functional error will likely occur, and it will likely take considerable time and effort to narrow down the source of the problem to the BGA connector. In trying to determine the cause of the error, it will be difficult to determine whether the connector is the cause or a component or the board itself. This complexity is compounded if two boards are connected together since it will be difficult to determine whether the error is coming from one board or the other. The problem is further compounded when multiple BGA connectors are used on a board.

Testing a mounted connector itself may require a tedious and time consuming ohm meter test of each connector pin. Unfortunately, the BGA connectors usually cannot simply be removed and replaced, and as the boards themselves are generally very expensive, they cannot simply be scrapped. Thus, to minimize time wasted chasing errors and minimize scrapping of boards, it is important to be able to accurately test mounted BGA connectors for opens.

In addition to testing mounted connectors for opens, a board including one or more unmated connectors may need to be functionally tested. Components on the board under test that interface with an unmated connector may be left with “undriven” input pins, and when power is applied to the board, the voltage level of each undriven input may float to an indeterminate value. Floating input pins may cause excessive power consumption or in extreme cases component failure. For example, the voltage level of an undriven CMOS input stage may float to a voltage level between the switching thresholds of the two complementary MOSFET transistors within the input stage (e.g., 2.4v+/−0.1v) causing both transistors to conduct. If the number of inputs in this state is large enough, power consumption and thermal characteristics may exceed the component's specifications. Furthermore, electromagnetic noise, superimposed on a floating input may cause the input voltage level to drift slowly in and out of the CMOS switching region. In fast, powerful CMOS gates this can cause oscillation at the gate output at frequencies greater than 100 MHz. If this condition is prolonged, component failure may occur. Thus, testing of a board with one or more unmated connectors, is often not done to prevent potential damage to undriven inputs.

### SUMMARY

Connector test cards provide for improved printed circuit board (“board”) testability by terminating each etch routed to an unmated connector on the board. With the connector test card mated with the connector on the board under test, the integrity of solder joints between the connector and the board may be tested for opens and shorts on a standard in-circuit or fixtureless tester. In addition, during functional testing, a connector test card may be mated with a connector on the board to prevent the voltage levels on undriven component inputs on the board from floating.

In one aspect, the present invention provides a connector test card, including a printed circuit board, a connector mounted to the printed circuit board, where the connector includes signal connections and resistors mounted to the printed circuit board to electrically connect at least a portion of the signal connections to at least one ground connection.

In another aspect, the present invention provides a method of testing a connector mounted to a printed circuit board, including mating a connector test card to the connector, attaching a first test probe to a first signal test pad on the printed circuit board, attaching a second test probe to a ground test pad on the printed circuit board, applying a voltage across the first signal test pad and the ground test pad, measuring the resistance across the first signal test pad and the ground test pad and detecting an open if the measured resistance across the first signal test pad and the ground test pad is greater than a predetermined threshold value.

In yet another aspect, the present invention provides a method of testing a connector mounted to a printed circuit board, including mating a connector test card to the connector, attaching a first test probe to a first signal test pad on the printed circuit board, attaching a second test probe to a second signal test pad on the printed circuit board, applying a voltage across the first and second signal test pads, measuring the resistance across the first and second signal test pads and detecting short if the measured resistance across the first and second signal test pads is less than a predetermined threshold value.

In still another aspect, the present invention provides a method of functionally testing a printed circuit board including an unmated connector and components, including mating a connector test card to the connector, where the connector test card terminates etch on the printed circuit board connected to the connector and connected to inputs of one or more of the plurality of components, and applying power to the printed circuit board.

### BRIEF DESCRIPTION OF THE DRAWINGS

FIG. 1 is an isometric view of a plug connector test card;

FIG. 2 is an isometric view of a receptacle connector test card;

FIG. 3 depicts a top and a bottom view of a board of a connector test card showing only board pads;

FIG. 4 depicts a top and a bottom view of a board of a connector test card showing only board pads and vias;

FIG. 5 depicts a top and a bottom view of a board of a connector test card showing board pads, vias and etch;

FIG. 6 depicts a bottom view of a board of a connector test card showing board pads, vias, etch and resistors mounted between signal board pads and ground board pads;

FIG. 7 is an isometric view of connector test card mated with a connector mounted to a board under test; and

FIG. 8 is an enlarged view of a portion of FIG. 7.

### DETAILED DESCRIPTION

Connector test cards provide for improved printed circuit board (“board”) testability. For instance, after mounting a ball grid array (“BGA”) connector (“mounted connector”) to a board, a connector test card may be temporarily mated with the mounted connector to terminate all of the mounted connector's signal pins. An in-circuit or fixtureless tester may then be used to detect invalid solder joints between connector ball pads and board pads (“opens”) and, in certain circumstances, to detect solder bridges between one connector ball pad/board pad solder joint and another connector ball pad/board pad solder joint (“shorts”). In addition, during functional testing, a connector test card may be mated with a connector (BGA or other) on the board to terminate all or only a portion of the signal pins to prevent the voltage levels on undriven component inputs on the board under test from floating.

In general, manufacturers of connectors sell receptacle connectors and mating plug connectors. If a board under test includes a mounted receptacle connector, then a plug connector test card, including a plug connector capable of mating with the mounted receptacle connector, is chosen for testing. Similarly, if a board under test includes a mounted plug connector, then a receptacle connector test card, including a receptacle connector capable of mating with the mounted plug connector, is chosen for testing.

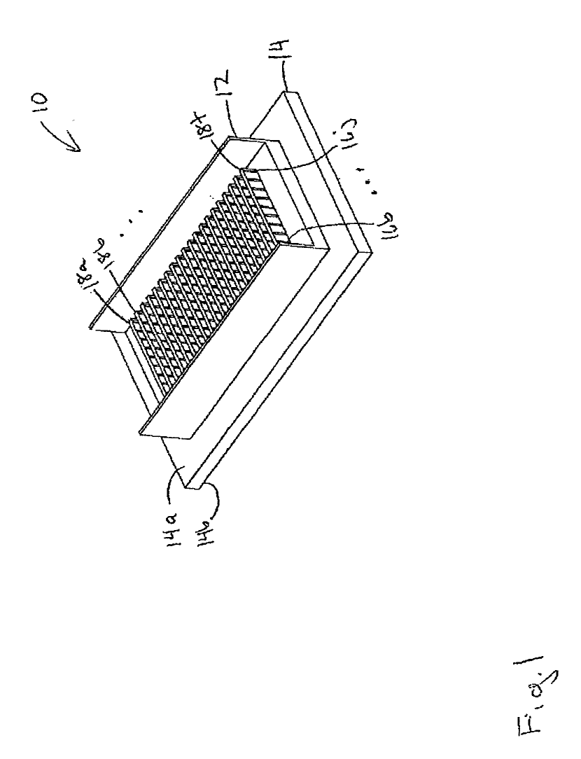

Referring to FIG. 1, a plug connector test card 10 includes a plug connector 12 mounted to a board 14. Many varieties of plug connectors are available. In this example, plug connector 12 is a BGA 2.5 mm NeXLev plug connector, part number 470-2025-100 and includes twenty wafers 18a-18t, each of which includes ten signal pins 16a-16j on one side and an integral stripline ground shield on the other side.

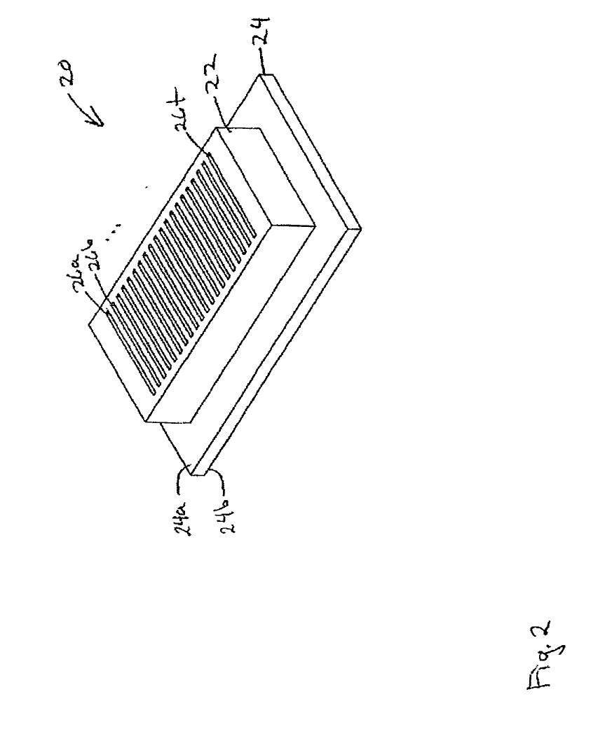

Referring to FIG. 2, a receptacle connector test card 20 includes a receptacle connector 22 mounted to a board 24. Many varieties of receptacle connectors are available. In this example, receptacle connector 22 is a BGA 10.5 mm NeXLev receptacle connector, part number 470-2105-100 and includes twenty receptacles 26a-26t, each of which is capable of receiving a wafer from a 2.5 mm NeXLev plug connector.

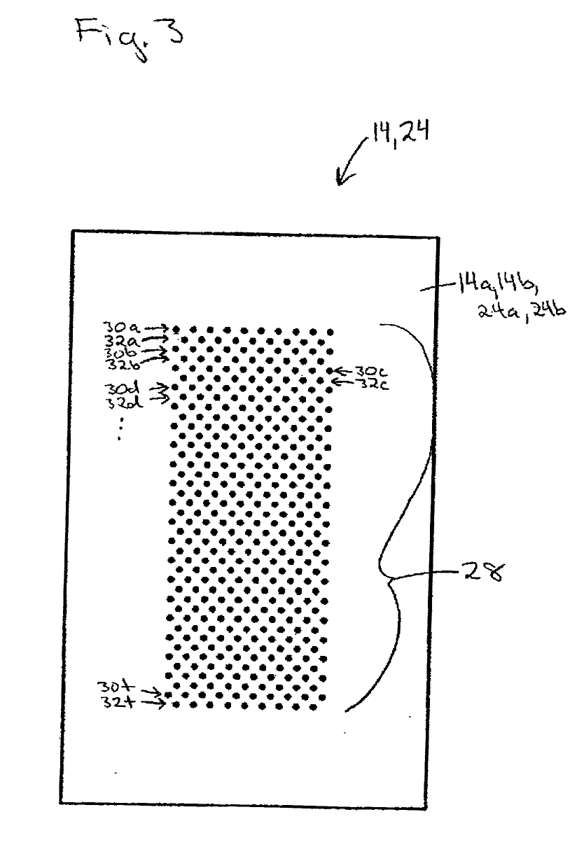

In one embodiment, the BGA patterns on the bottom of plug connector 12 and receptacle connector 22 are identical. Thus, top side 14a (FIG. 1) and 24a (FIG. 2) of boards 14 and 24, respectively, on which the BGA plug and receptacle connectors, respectively, are mounted include an identical arrangement 28 (FIG. 3) of board pads. In this example, rows 30a-30t of signal board pads alternate with rows 32a-32t of ground board pads in accordance with the BGA pattern on the bottom of the plug and receptacle connectors.

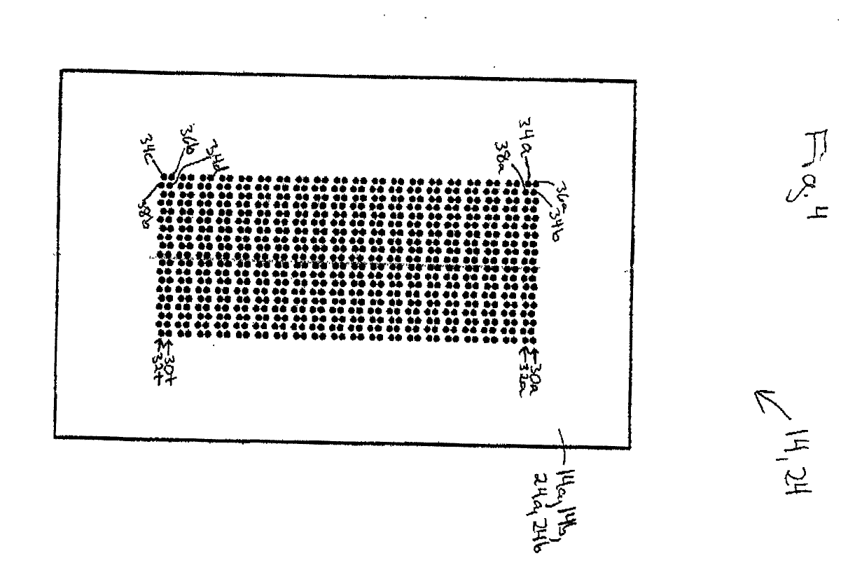

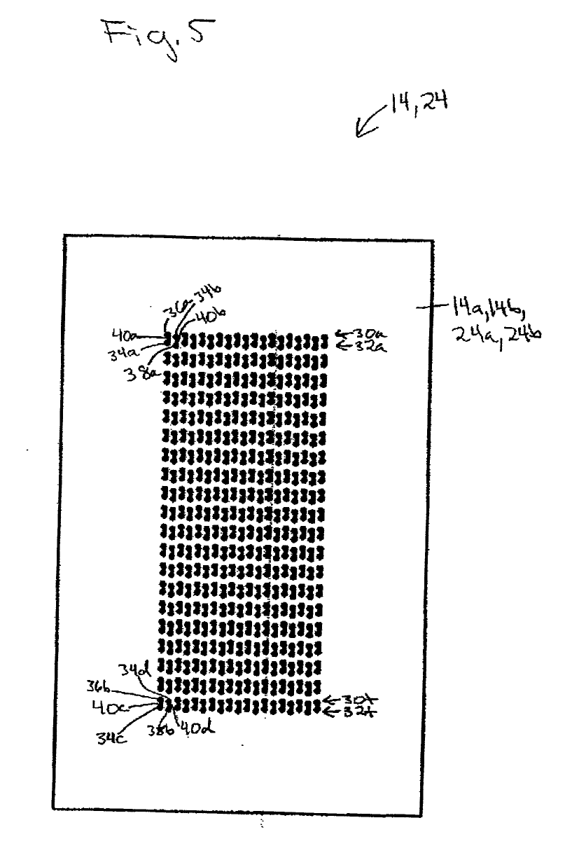

In addition to board pads, each board 14, 24 includes vias located adjacent to each board pad and etch connecting each board pad to an adjacent via. Referring to FIG. 4, for example, via 34a is located just below signal board pad 36a in row 30a, and via 34b is located just above ground board pad 38a in row 32a. As another example, via 34c is located just below signal board pad 36b in row 30t, and via 34d is located just above ground board pad 38b in row 32t. Referring to FIG. 5, etch 40a electrically connects via 34a with signal board pad 36a, and etch 40b electrically connects via 34b with signal board pad 38a. Similarly, etch 40c electrically connects via 34c with signal board pad 36b, and etch 40d electrically connects via 34d with signal board pad 38b. The vias run through the board to the bottom side 14b (FIG. 1) and 24b (FIG. 2), and in one embodiment, the pattern of signal and ground board pads, the adjacent vias and the etch connecting each via to each board pad is identical on both sides of boards 14 and 24.

As previously mentioned, ball pads of BGA plug connector 10 are surface mounted to board pads in rows 30a-30t and 32a-32t on top side 14a of board 14 and ball pads of BGA receptacle connector 22 are surface mounted to board pads in rows 30a-30t and 32a-32t on top side 24a of board 24. On bottom sides 14b and 24b, resistors may be used to electrically connect each board pad to a ground pad. Thus, when a plug connector test card is mated with a receptacle connector mounted to a board under test or when a receptacle connector test card is mated with a plug connector mounted to a board under test, each of the signal pins are terminated.

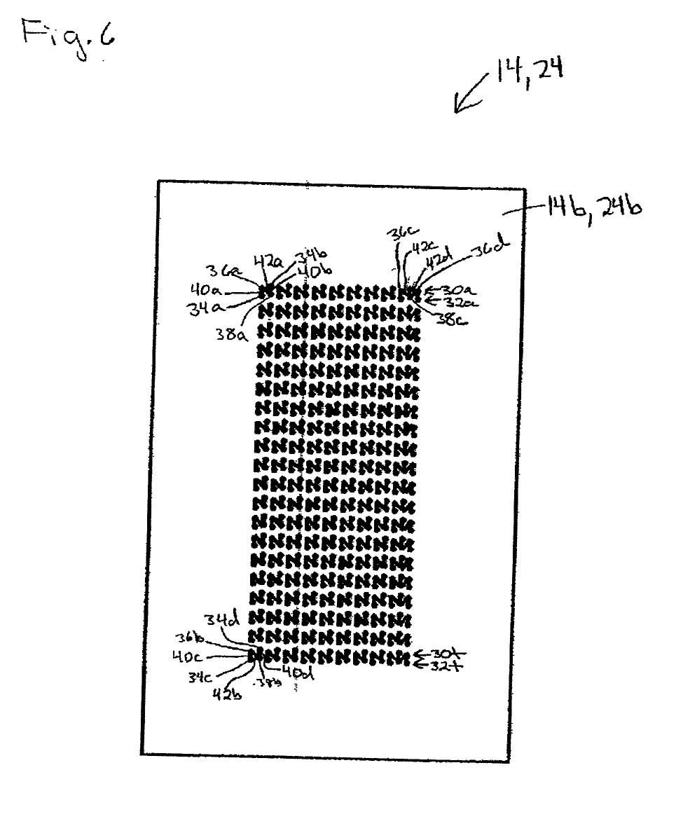

Referring to FIG. 6, for example, resistor 42a is electrically connected between signal board pad 36a and ground board pad 38a, and resistor 42b is electrically connected between signal board pad 36b and ground board pad 38b. Where, as in this example, there are more signal board pads than ground board pads, multiple signal board pads may be connected to the same ground board pad. For example, both signal board pads 36c and 36d may be electrically connected to ground board pad 38c through resistors 42c and 42d, respectively.

In the current example, the resistors (e.g., 42a-42d) may be standard 0402 resistors (40 mils×20 mils) that fit within the distance between each signal board pad and an adjacent ground board pad. If other connectors are used, the distance between the ball pads may be changed and a different type of resistor may need to be used. In addition, instead of a resistor, a jumper, wire or other connection mechanism may be used to connect each signal board pad to a ground board pad, and the resistor or other connector need not be located between the signal and ground board pads.

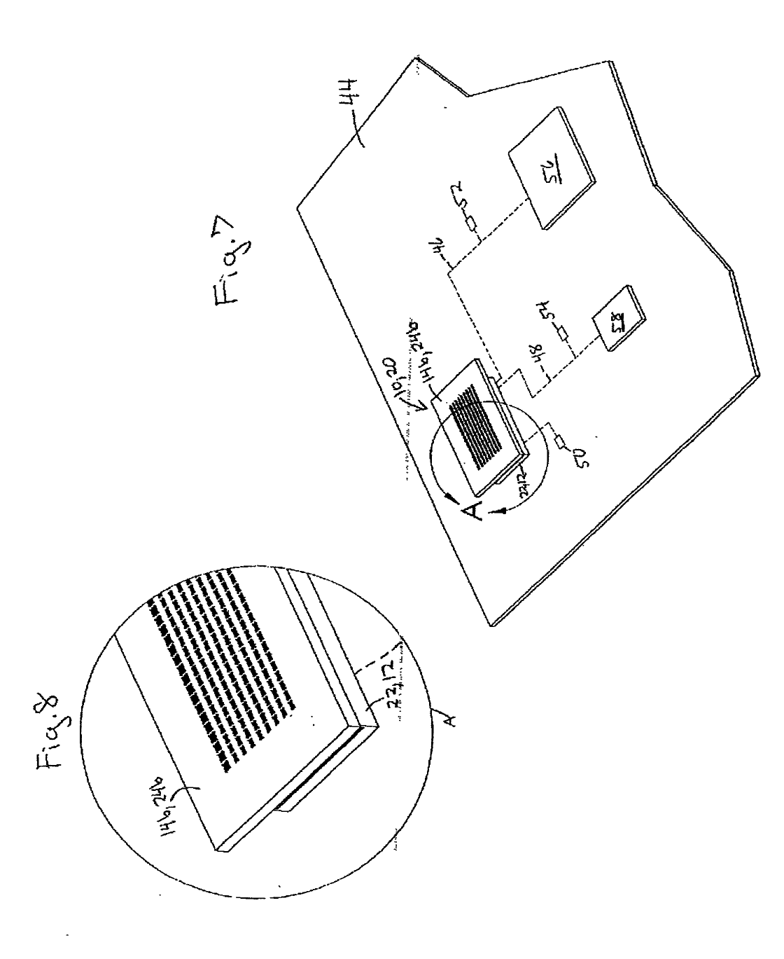

To allow the solder joints connecting a board under test to a mounted connector to be tested for opens on an in-circuit tester, a low impedance value, for example, 0 ohms, may be chosen for the resistors (e.g., 42a-42d, FIG. 6) mounted on connector test card boards 14, 24 (“low impedance connector test card”). Referring to FIG. 7, when a low impedance connector test card (e.g., 10 or 20) is mated with a connector (e.g., 22 or 12, respectively) mounted to a board 44 under test, each etch (e.g., 46, 48) connected to the mounted connector is effectively terminated (i.e., shorted) to ground. A low impedance value may be chosen to ensure current flow through the solder joint under test. Many low impedance values may be chosen, for example, 0, 10, 40 ohms.

The in-circuit tester may then be used to test the integrity of the solder joint between the ball pad for each signal pin on the connector and each corresponding board pad on the board under test. For each signal pin in the connector and corresponding connected etch, the in-circuit tester connects to an associated signal test pad and a ground test pad on the board under test. For instance, to test etch 46, the in-circuit tester connects with signal test pad 52 and a ground pad (e.g., 50), and to test etch 48, the in-circuit tester connects with signal test pad 54 and a ground pad (e.g., 50). Each etch (e.g., 46, 48) runs from a signal pin on the connector to a component (e.g., 56, 58). Etch may be routed from several signal pins on the connector to the same component or different components on the board under test. The ground test pad may or may not be connected to a ground pin on the mounted connector, and there may be multiple ground test pads.

For each signal pin, the in-circuit tester applies a voltage across the ground pad and signal test pad. If a low impedance, for example, less than 10 ohms, is detected, then the in-circuit tester determines that the solder joint between the ball pad on the connector and the board pad on the board under test is valid. If a higher impedance is detected, then the in-circuit tester determines that solder joint is “open” or invalid and notifies the tester operator.

Connector test cards may be used as part of the manufacturing process to ensure that BGA connectors are properly mounted to printed circuit boards. In addition, connector test cards may be used after manufacturing whenever the solder joints of a BGA connector are in doubt. For example, after a connector pair has been mated and un-mated many times, a solder joint may break—that is, become open. Connector test cards may be used to test the integrity of the connectors on each board to determine where the solder joint break is located.

Using a low impedance value for the resistors (e.g., 42a-42d, FIG. 6) mounted on the connector test card effectively shorts all the signal pins on the connector and each corresponding etch on the board under test to ground. Thus, a low impedance connector test card cannot be used to test for shorts between signal pins on the mounted connector. To test for both opens and shorts, a higher impedance is chosen for the resistors mounted on the connector test card (“high impedance connector test card”) such that each signal pin on the mounted connector and corresponding etch on the board under test remains a separate, terminated circuit. The impedance value chosen depends on the technology of the board under test and the components it carries. For CMOS technology, a standard value for a pull-down resistor is 270 ohms. Thus, the resistors on the high impedance connector test card may all have a impedance value of, for example, 270 ohms. Many other values may also be chosen, for example, 1,000 ohms.

To test for shorts between signal pins on the mounted connector, the in-circuit tester connects to two different signal test pads, for example, 52 and 54, and applies a voltage (e.g., 5v) across the two pads. If there is no short between the two signal pins connected to the signal test pads, the in-circuit tester should detect an impedance of about two times the impedance value chosen for the resistors mounted on the connector test card (e.g., 540 ohms). To allow for some tolerance, if the in-circuit tester detects an impedance of greater than, for example, 400 ohms, the in-circuit tester will determine that there is no short between those two signal pins, and if the in-circuit tester detects an impedance of less than 400 ohms, the in-circuit tester will determine that there is a short and notify the tester operator.

Testing for opens between ball pads on the mounted connector and board pads on the board under test is performed in a similar manner for both the low and high impedance connector test cards. However, when the high impedance connector test card is used, the in-circuit tester looks for a higher impedance value when a voltage is applied between the signal test pad and the ground test pad. For example, if the high impedance connector test card includes 270 ohm resistors and the in-circuit tester detects an impedance of greater than, for example, 300 ohms, the in-circuit tester will determine that the solder joint for that signal pin is invalid or open. If the in-circuit tester detects an impedance of less than 300 ohms, then the in-circuit tester will determine that the solder joint is valid. Thus, a low impedance connector test card may be used to allow an in-circuit tester to detect opens between signal pin ball pads on the connector and board pads on the board under test but a high impedance connector test card may be used to allow an in-circuit tester to detect both shorts between connector signal pin solder joints and opens between signal pin ball pads on the connector and board pads on the board under test.

In addition to testing a mounted connector for shorts and opens, a high impedance connector test card may be used when a board under test, including an unmated mounted connector, is to be functionally tested. Functional testing requires that power be applied to the board under test and that the components perform in accordance with their specifications. Having an unmated connector on the board under test may mean that certain component inputs are “undriven”. Undriven inputs may float and cause excessive power consumption, heat generation and, potentially, permanent damage to the component. Mating a mounted connector on the board under test with a high impedance connector test card insures that all undriven inputs are terminated and, thus, cannot float.

Instead of using a high impedance connector test card that terminates each signal pin to ground, a partially populated high impedance connector test card may be used that only terminates particular signals (e.g., undriven inputs) to ground. In general, the high impedance connector test card is preferred to the partially populated high impedance connector test card because the high impedance connector test card may be mounted to any mounted connector—with which it may be mated—on any board under test whereas the partially populated high impedance test card will be specific to a particular type of board and a particular location if the board includes multiple mounted connectors. In addition, although the partially populated high impedance connector test card includes less resistors, the manufacturing process of applying a resistor to each ball pad/ground pad for the high impedance connector test card, in general, is less expensive than the cost of only applying resistors to particular ball pads/ground pads for the partially populated high impedance connector test card.

Instead of mounting resistors of the same impedance to a connector test card, resistors having different impedances may be mounted to a connector test card. The impedance values are chosen in accordance with the technology of the board and the particular signal pin location. Hence, a varying impedance connector test card, like the partially populated high impedance connector test card, will be specific to a particular type of board and a particular location if the board includes multiple connectors.

It will be understood that variations and modifications of the above described methods and apparatuses will be apparent to those of ordinary skill in the art and may be made without departing from the inventive concepts described herein. Accordingly, the embodiments described herein are to be viewed merely as illustrative, and not limiting, and the inventions are to be limited solely by the scope and spirit of the appended claims.

1. A connector test card, comprising:
a printed circuit board;
a connector mounted to the printed circuit board, wherein the connector includes a plurality of signal connections; and
a plurality of resistors mounted to the printed circuit board to electrically connect at least a portion of the plurality of signal connections to at least one ground connection.

2. The connector test card of claim 1, wherein the connector is mounted to a first side of the printed circuit board and the plurality of resistors are mounted to a second side of the printed circuit board.

3. The connector test card of claim 1, wherein the plurality of resistors electrically connect all of the plurality of signal connections to the at least one ground connection.

4. The connector test card of claim 1, wherein the plurality of resistors electrically connect the plurality of signal connections to a plurality of ground connections.

5. The connector test card of claim 1, wherein the connector is a plug connector and the plurality of signal connections comprise a plurality of signal pins.

6. The connector test card of claim 1, wherein the connector is a receptacle connector and the plurality of signal connections comprise a plurality of signal receptacles.

7. The connector test card of claim 1, wherein the plurality of resistors have a low impedance.

8. The connector test card of claim 7, wherein the impedance is 0 ohms.

9. The connector test card of claim 1, wherein the plurality of resistors have a high impedance.

10. The connector test card of claim 9, wherein the impedance is 270 ohms.

11. The connector test card of claim 1, wherein each of the plurality of resistors comprises the same impedance.

12. The connector test card of claim 1, wherein the plurality of resistors include a first portion of resistors having a first impedance and a second portion of resistors having a second impedance.

13. The connector test card of claim 12, wherein the plurality of resistors further include a third portion of resistors having a third impedance.

14. The connector test card of claim 1, wherein the connector includes a package with a ball grid array and the printed circuit board includes a corresponding first array of board pads on a first side.

15. The connector test card of claim 14, wherein the printed circuit board further includes an array of vias corresponding to the first array of board pads and a first plurality of etch connecting the first array of board pads to the array of vias.

16. The connector test card of claim 15, wherein the printed circuit board further includes a second array of board pads on a second side and a second plurality of etch connecting the second array of board pads to the array of vias.

17. The connector test card of claim 16, wherein the first and second arrays of board pads include signal board pads and ground board pads and wherein each of the plurality of resistors are mounted between one of the signal board pads and one of the ground board pads.

18. A method of testing a connector mounted to a printed circuit board, comprising:
mating a connector test card to the connector;
attaching a first test probe to a first signal test pad on the printed circuit board;
attaching a second test probe to a ground test pad on the printed circuit board;
applying a voltage across the first signal test pad and the ground test pad;
measuring the resistance across the first signal test pad and the ground test pad; and
detecting an open if the measured resistance across the first signal test pad and the ground test pad is greater than a predetermined threshold value.

19. The method of claim 18, further comprising:
attaching the first test probe to a second signal test pad on the printed circuit board;
applying a voltage across the second signal test pad and the ground test pad;
measuring the resistance across the second signal test pad and the ground test pad; and
detecting another open if the measured resistance across the second signal test pad and the ground test pad is greater than the predetermined threshold value.

20. The method of claim 18, further comprising:
attaching the second test probe to a second signal test pad on the printed circuit board;
applying a voltage across the first and second signal test pads;
measuring the resistance across the first and second signal test pads; and
detecting a short if the measured resistance across the first and second signal test pads is less than another predetermined threshold value.

21. The method of claim 20, further comprising:
attaching the second test probe to a third signal test pad on the printed circuit board;
applying a voltage across the first and third signal test pads;
measuring the resistance across the first and third signal test pads; and
detecting a short if the measured resistance across the first and third signal test pads is less than the another predetermined threshold value.

22. The method of claim 18, wherein the connector is a plug connector and the connector test card is a receptacle connector test card.

23. The method of claim 18, wherein the connector is a receptacle connector and the connector test card is a plug connector test card.

24. A method of testing a connector mounted to a printed circuit board, comprising:
mating a connector test card to the connector;
attaching a first test probe to a first signal test pad on the printed circuit board;
attaching a second test probe to a second signal test pad on the printed circuit board;
applying a voltage across the first and second signal test pads;
measuring the resistance across the first and second signal test pads; and
detecting short if the measured resistance across the first and second signal test pads is less than a predetermined threshold value.

25. A method of functionally testing a printed circuit board including an unmated connector and a plurality of components, comprising:
mating a connector test card to the connector, wherein the connector test card terminates etch on the printed circuit board connected to the connector and connected to inputs of one or more of the plurality of components; and
applying power to the printed circuit board.

26. The method of claim 25, wherein the connector test card includes resistors tied to at least one ground connection to terminate the etch on the printed circuit board connected to the connector and connected to inputs of one or more of the plurality of components.

27. The method of claim 25, wherein the connector test card terminates each etch on the printed circuit board connected to the connector.

28. The method of claim 25, wherein the connector is a plug connector and the connector test card is a receptacle connector test card.

29. The method of claim 25, wherein the connector is a receptacle connector and the connector test card is a plug connector test card.
